(19) United States
(12) Patent Application Publication
(10) Pub. No.: US 2023/0043715 A1
(43) Pub. Date: Feb. 9, 2023

(54) PROBE, PROBE DEVICE, AND INSPECTION METHOD

(71) Applicant: Sumitomo Electric Industries, Ltd., Osaka-shi (JP)

(72) Inventor: Mitsuharu HIRANO, Osaka-shi (JP)

(73) Assignee: Sumitomo Electric Industries, Ltd., Osaka-shi (JP)

(21) Appl. No.: 17/858,333

(22) Filed: Jul. 6, 2022

(30) Foreign Application Priority Data
Aug. 3, 2021 (JP) 2021-127308

(51) Int. Cl. G01R 1/073

(52) U.S. Cl. CPC G01R 1/07314

(57) ABSTRACT

A probe according to an embodiment is a probe used in inspecting an electronic device. The probe includes an end portion capable of contacting a surface of an electrode of the electronic device. The end portion has a recessed portion.

### CROSS REFERENCE TO RELATED APPLICATIONS

This application claims priority based on Japanese Patent Application No. 2021-127308 filed on Aug. 3, 2021, and the entire contents of the Japanese patent application are incorporated herein by reference.

### TECHNICAL FIELD

The present disclosure relates to a probe, a probe device, and an inspection method.

### BACKGROUND

Patent Document 1 (Japanese Unexamined Patent Application Publication No. 2002-250744) discloses a probe needle for inspecting a semiconductor device. The probe needle includes an end portion having a spherically curved surface. By sliding the end portion of the probe needle on a surface of an electrode, an oxide film on the surface is scraped. As a result, the probe needle and the electrode are electrically connected to each other.

### SUMMARY OF THE INVENTION

A probe according to an aspect of the present disclosure is a probe used in inspecting an electronic device. The probe includes an end portion capable of contacting a surface of an electrode of the electronic device. The end portion has a recessed portion.

A probe device according to another aspect of the present disclosure includes a plurality of probes and a probe card to which the plurality of probes are to be attached. The plurality of probes are each the probe described above.

An electronic device inspection method according to another aspect of the present disclosure includes contacting the end portion of the probe described above with the surface of the electrode, and inspecting an electrical characteristic of the electronic device with the end portion of the probe and the surface of the electrode in contact with each other.

### BRIEF DESCRIPTION OF THE DRAWINGS

FIG. 1 is a schematic view of an inspection device including a probe device according to an embodiment.

FIG. 2 is a schematic perspective view of a part of a probe according to an embodiment.

FIG. 3 is a side view of the probe in FIG. 2.

FIG. 4 is a plan view of an end portion of the probe in FIG. 2.

FIG. 5 is a flowchart illustrating an inspection method according to an embodiment.

FIG. 6 is a plan view illustrating an example of a surface of an electrode.

FIG. 7 is a side view of a part of a probe according to another embodiment.

FIG. 8 is a side view of a part of a probe according to another embodiment.

FIG. 9 is a plan view of an end portion of the probe in FIG. 8.

FIG. 10 is a side view of a part of a probe according to another embodiment.

FIG. 11 is a plan view of an end portion of the probe in FIG. 10.

FIG. 12 is a side view of a part of a probe according to another embodiment.

FIG. 13 is a plan view of an end portion of the probe in FIG. 12.

FIG. 14 is a side view of a part of a probe according to another embodiment.

FIG. 15 is a plan view of an end portion of the probe in FIG. 14.

### DETAILED DESCRIPTION

Since an end portion of a probe needle has a curved surface, a contact area between the end portion of the probe needle and a surface of an electrode is relatively large. Therefore, a pressure with which the end portion of the probe needle presses the surface of the electrode is reduced, and thus an oxide film on the surface of the electrode may not be removed.

The present disclosure provides a probe, a probe device, and an inspection method capable of reducing a contact area with a surface of an electrode.

A probe according to an aspect of the present disclosure is a probe used in inspecting an electronic device. The probe includes an end portion capable of contacting a surface of an electrode of the electronic device. The end portion has a recessed portion.

According to the probe, since the end portion of the probe has the recessed portion, a contact area between the end portion of the probe and the surface of the electrode can be reduced.

The recessed portion may be a groove extending so as to cross the end portion. In this case, shavings generated when the end portion of the probe scrapes the surface of the electrode can be discharged from the end portion of the groove.

A depth of the recessed portion may be 100 μm or larger. In this case, when the end portion of the probe is pressed against the surface of the electrode, even if the surface of the electrode is scraped, a bottom of the recessed portion is less likely to contact the surface of the electrode.

A depth of the recessed portion may be 1000 μm or smaller. In this case, when the end portion of the probe is pressed against the surface of the electrode, the end portion of the probe is less likely to be broken.

The probe may include a first portion and a second portion connecting to the first portion. The first portion may extend in a first direction. The second portion may extend in a second direction intersecting the first direction. The second portion may include the end portion. In this case, the probe can be bent between the first portion and the second portion.

A probe device according to an embodiment includes a plurality of probes and a probe card to which the plurality of probes are to be attached. The plurality of probes are each the probe described above.

According to the probe device, since the end portion of each of the probes has the recessed portion, the contact area between the end portion of each of the probes and the surface of the electrode can be reduced.

An electronic device inspection method according to an embodiment includes contacting the end portion of the probe described above with the surface of the electrode, and inspecting an electrical characteristic of the electronic device with the end portion of the probe and the surface of the electrode in contact with each other.

According to the inspection method, since the end portion of the probe has the recessed portion, the contact area between the end portion of the probe and the surface of the electrode can be reduced.

In the contacting, the end portion may be brought into contact with a plurality of first regions of the surface of the electrode. In the inspecting, a first electrical characteristic of the electronic device may be inspected with the end portion of the probe and the plurality of first regions of the surface of the electrode in contact with each other. The inspection method may further includes, after inspecting the first electrical characteristic, contacting the end portion of the probe with a plurality of second regions of the surface of the electrode and inspecting a second electrical characteristic of the electronic device with the end portion of the probe and the plurality of second regions of the surface of the electrode in contact with each other. The plurality of first regions and the plurality of second regions may be alternately arranged so that one second region of the plurality of second regions is disposed between adjacent ones of the plurality of first regions. In this case, as compared with a case where a probe having no recessed portion is used, a region for performing a plurality of inspections can be made smaller.

### Details of Embodiments of the Present Disclosure

Hereinafter, embodiments according to the present disclosure will be described in detail with reference to the accompanying drawings. In the description of the drawings, like or corresponding elements are denoted by like reference numerals, and redundant descriptions thereof will be omitted. In the drawings, an XYZ orthogonal coordinate system is shown as necessary.

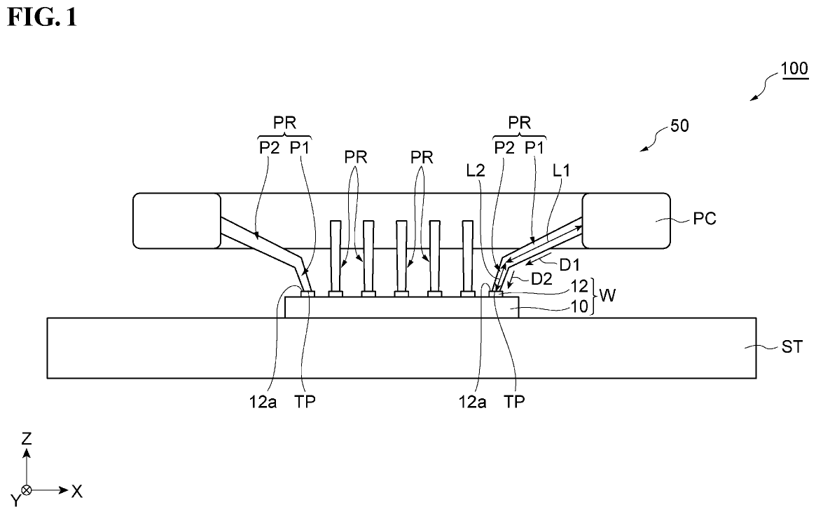

FIG. 1 is a schematic view of an inspection device including a probe device according to an embodiment. Inspection device 100 used for an electronic device W shown in FIG. 1 is, for example, a semiconductor testing apparatus. Inspection device 100 can inspect an electrical characteristic of electronic device W.

Electronic device W may include a substrate 10 and an electrode 12 provided on substrate 10. Electronic device W may be a semiconductor device or may be a printed wiring board. Substrate 10 may be a semiconductor substrate such as a silicon substrate, or may be an insulating substrate. Electronic device W may include a plurality of electrodes 12. The number of electrodes 12 may be 100 or more. Each of electrodes 12 is, for example, an electrode pad. Each of electrodes 12 contains a metal such as aluminum or gold. Each of electrodes 12 may include an oxide film such as an aluminum oxide film on a surface 12a.

Inspection device 100 may include a support body ST and a probe device 50. Support body ST supports electronic device W. Support body ST is, for example, an electrostatic chuck. Support body ST may be movable in an X-axis direction, a Y-axis direction, and a Z-axis direction, or may be rotatable around a Z-axis.

Probe device 50 may include a plurality of probes PR and a probe card PC to which the plurality of probes PR are to be attached. Each of probes PR is used for inspection of electronic device W. The number of probes PR may be two or more, 100 or more, or 1000 or less. Probe card PC may be a wiring substrate that is electrically connected to each of probes PR. Probe card PC may be connected to a tester via a wiring.

Each of probes PR includes an end portion TP capable of contacting surface 12a of electrode 12 of electronic device W. By relative movement of support body ST with respect to electronic device W, end portion TP of each probe PR can be brought into contact with surface 12a of electrode 12, or end portion TP of each probe PR can be separated from surface 12a of electrode 12. Each of probes PR may include a first portion P1 and a second portion P2 connecting first portion P1. First portion P1 extends in a first direction D1. Second portion P2 extends in a second direction D2 intersecting first direction D1. An angle formed by first direction D1 and second direction D2 may be an obtuse angle. An angle between first direction D1 and a direction (e.g., X-axis direction or Y-axis direction) orthogonal to Z-axis direction may be less than 45°. An angle between second direction D2 and Z-axis direction may be less than 45°. A first end of first portion P1 is to be connected to probe card PC. A second end of first portion P1 is connected to a base end of second portion P2. Second portion P2 includes end portion TP. Probe PR may function as a cantilever.

A length L1 of first portion P1 in first direction D1 may be 1000 μm or longer. A length L2 of second portion P2 in second direction D2 may be shorter than length L1. Length L2 may be 100 μm or longer, or may be 10000 μm or shorter.

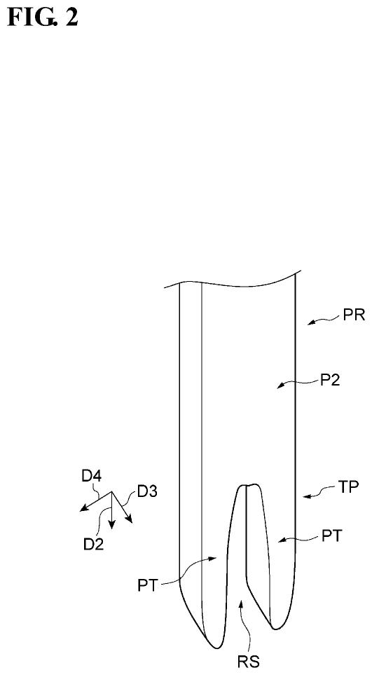

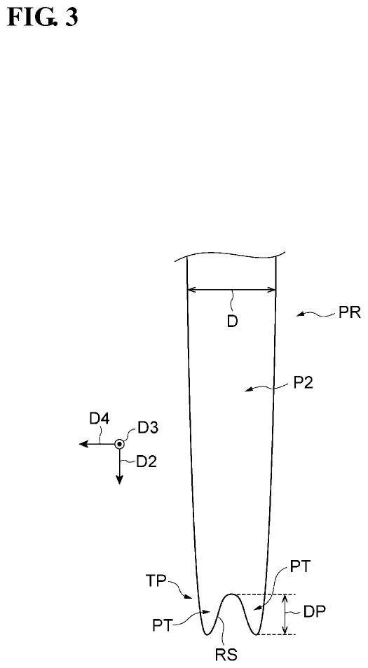

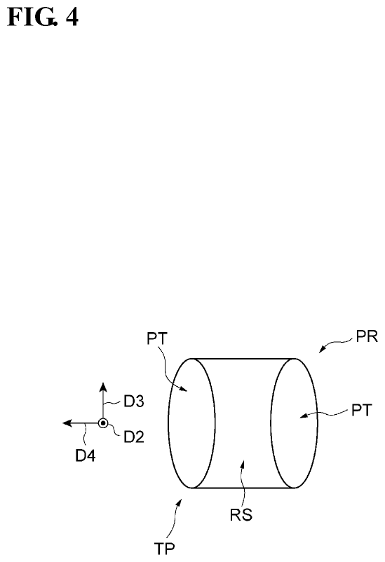

FIG. 2 is a schematic perspective view of a part of a probe according to an embodiment. FIG. 3 is a side view of the probe in FIG. 2. FIG. 4 is a plan view of an end portion of the probe in FIG. 2. As shown in FIGS. 2 to 4, end portion TP of probe PR has a recessed portion RS. Recessed portion RS has a depth DP in second direction D2 (a direction in which end portion TP of probe PR protrudes). Depth DP of recessed portion RS may be 1 μm or larger, 100 μm or larger, or 1000 μm or smaller. Recessed portion RS may be a groove extending so as to cross end portion TP. The groove may extend in a third direction D3 orthogonal to second direction D2 in a plane including first direction D1 and second direction D2. Each of ends of the groove may reach an edge of probe PR in third direction D3. End portion TP of probe PR may include a plurality of (for example, two) protrusions PT. Recessed portion RS may be formed between the plurality of protrusions PT. In a fourth direction D4 orthogonal to both second direction D2 and third direction D3, recessed portion RS may be disposed between the plurality of protrusions PT. Each of protrusions PT has a height in second direction D2. A top surface of each of protrusions PT may have a curved surface. A cross-sectional area of each of protrusions PT orthogonal to second direction D2 gradually decreases toward the top surface. A cross-section of each of protrusions PT orthogonal to second direction D2 may have, for example, an elliptical shape with a direct axis extending in third direction D3.

Second portion P2 of probe PR may have a dimension D in a direction orthogonal to second direction D2. Dimension D may be 10 μm or larger, 1000 μm or smaller, or 50 μm or smaller. Dimension D may be a maximum value of a dimension of second portion P2 in the direction orthogonal to second direction D2.

Examples of materials for probe PR include tungsten, rhenium, iridium, rhodium, beryllium, palladium, platinum, gold, silver, copper, and alloys thereof.

Recessed portion RS may be formed by etching, or may be formed by machining. When recessed portion RS is formed by etching, recessed portion RS may be formed as follows. First, a mask having an opening corresponding to recessed portion RS is formed on an end portion of probe PR by photolithography. Next, recessed portion RS is formed by immersing the end portion of probe PR in an etchant. Depth DP of recessed portion RS can be controlled by, for example, an etching time, a type of an etchant or the like.

According to probe PR and probe device 50 of the present embodiment, since end portion TP of probe PR has recessed portion RS, a bottom of recessed portion RS does not contact surface 12a of electrode 12. Therefore, a contact area between end portion TP of probe PR and surface 12a of electrode 12 can be made smaller than that of a probe having no recessed portion RS. Therefore, even if a force applied to probe PR is small, end portion TP of probe PR can be pressed against surface 12a of electrode 12 with a relatively high pressure. As a result, end portion TP of probe PR can scrape surface 12a of electrode 12.

When probe PR includes first portion P1 and second portion P2, probe PR can be bent between first portion P1 and second portion P2.

When recessed portion RS is a groove, shavings generated when end portion TP of probe PR scrapes surface 12a of electrode 12 can be discharged from both ends of the groove.

In a case where depth DP of recessed portion RS is 100 μm or larger, when end portion TP of probe PR is pressed against surface 12a of electrode 12, even if surface 12a of electrode 12 is scraped, a bottom of recessed portion RS is less likely to contact surface 12a of electrode 12. Therefore, a probe mark formed when end portion TP of probe PR scrapes surface 12a of electrode 12 can be made smaller.

In a case where depth DP of recessed portion RS is 1000 μm or smaller, end portion TP of probe PR is less likely to be broken when end portion TP of probe PR is pressed against the surface 12a of electrode 12.

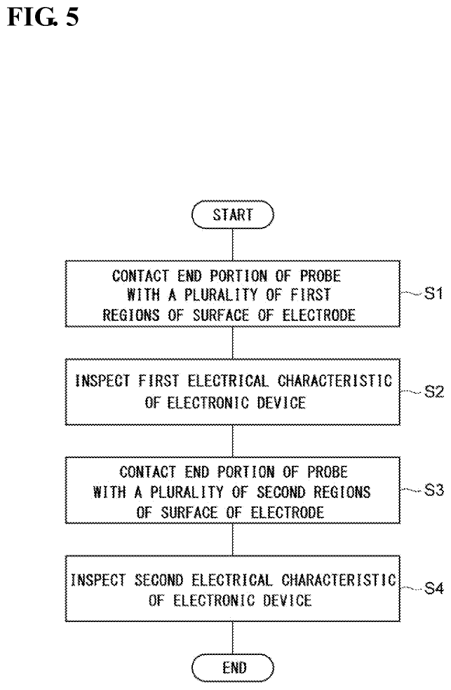

FIG. 5 is a flowchart illustrating an inspection method according to an embodiment. As shown in FIG. 5, the inspection method of electronic device W may include a step S1, a step S2, a step S3, and a step S4. Steps S1 to S4 may be performed in sequence. The inspection method of electronic device W may not include step S3 and step S4. The inspection method of electronic device W may be performed as follows, for example using the inspection device in FIG. 1.

In step S1, end portion TP of probe PR is brought into contact with surface 12a of electrode 12. In a case where the protruding direction (second direction D2) of end portion TP of probe PR is deviated from a normal direction (Z-axis direction) of surface 12a of electrode 12, when end portion TP of probe PR is pressed against surface 12a of electrode 12, end portion TP of probe PR slides along surface 12a of electrode 12. Accordingly, since surface 12a of electrode 12 is scraped, a probe mark is formed on surface 12a of electrode 12. Since end portion TP of probe PR slides in a direction orthogonal to Z-axis direction, the probe mark also extends along the same direction. A load applied to each of probes PR may be determined based on the shape, material, pressing amount (overdrive amount), and the like of probes PR. A depth of the probe mark is, for example, smaller than 100 μm.

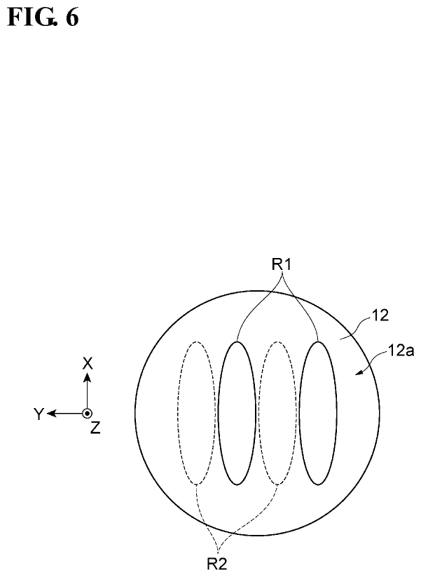

FIG. 6 is a plan view illustrating an example of a surface of an electrode. As shown in FIG. 6, in step S1, end portion TP may be brought into contact with a plurality of first regions R1 of surface 12a of electrode 12. Each of first regions R1 extends in, for example, X-axis direction. When probe PR shown in FIGS. 2 to 4 is used, a plurality of protrusions PT provided in end portion TP of probe PR each contact the plurality of first regions R1. When end portion TP of probe PR is pressed against surface 12a of electrode 12, end portion TP of probe PR slides along the plurality of first regions R1. As a result, probe marks are formed in the plurality of first regions R1. Since recessed portion RS of end portion TP of probe PR does not contact surface 12a of electrode 12, a probe mark may not be formed between first regions R1.

In step S2, a first electrical characteristic of electronic device W is inspected with end portion TP of probe PR and the plurality of first regions R1 of surface 12a of electrode 12 in contact with each other. In the inspection, an input voltage is supplied from a tester to electronic device W via probe PR. A signal output from electronic device W in accordance with the input voltage is sent to the tester via probe PR. The tester determines whether or not the first electrical characteristic of electronic device W is within a desired characteristic range based on the signal. If the first electrical characteristic of electronic device W is within a desired characteristic range, electronic device W is determined to be non-defective. After the inspection ends, end portion TP of probe PR is separated from surface 12a of electrode 12.

In step S3, end portion TP of probe PR is brought into contact with a plurality of second regions R2 of surface 12a of electrode 12. Step S3 may be performed in the same manner as step S1 except that a region to be brought into contact with end portion TP of probe PR is different. The plurality of first regions R1 and the plurality of second regions R2 are alternately arranged in, for example, Y-axis direction such that one second region R2 is arranged between first regions R1 adjacent to each other. The plurality of second regions R2 may not overlap the plurality of first regions R1.

In step S4, a second electrical characteristic of electronic device W is inspected with end portion TP of probe PR and the plurality of second regions R2 of surface 12a of electrode 12 in contact with each other. Step S4 may be performed in the same manner as step S2 except that a region to be brought into contact with end portion TP of probe PR is different. The second electrical characteristic may be the same as or different from the first electrical characteristic inspected in step S2. After the inspection ends, end portion TP of probe PR is separated from surface 12a of electrode 12.

After step S4, electronic device W which is determined to be non-defective in step S2 and step S4 are sorted and may be shipped as a product. In this way, electronic device W may be manufactured.

According to the inspection method of electronic device W of the present embodiment, since end portion TP of probe PR has recessed portion RS, a contact area between end portion TP of probe PR and surface 12a of electrode 12 can be reduced. Therefore, even if a force applied to probe PR is small, end portion TP of probe PR can be pressed against surface 12a of electrode 12 with a relatively high pressure.

When step S3 and step S4 are performed, since the plurality of first regions R1 and the plurality of second regions R2 are alternately arranged, it is possible to reduce a region for performing a plurality of inspections, as compared with a case where a probe having no recessed portion RS is used.

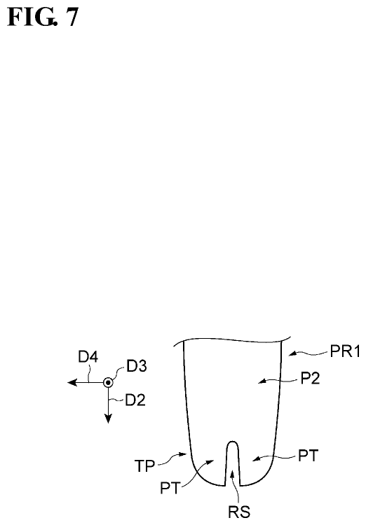

FIG. 7 is a side view of a part of a probe according to another embodiment. A probe PR1 shown in FIG. 7 has the same configuration as probe PR shown in FIGS. 2 to 4 except that the shape of recessed portion RS is different. Recessed portion RS of probe PR1 is, for example, a groove having a predetermined width. An inner wall of recessed portion RS of probe PR1 extends along a plane including, for example, second direction D2 and third direction D3. Recessed portion RS of probe PR1 may be formed by machining. According to probe PR1, the same effect as that of probe PR can be obtained.

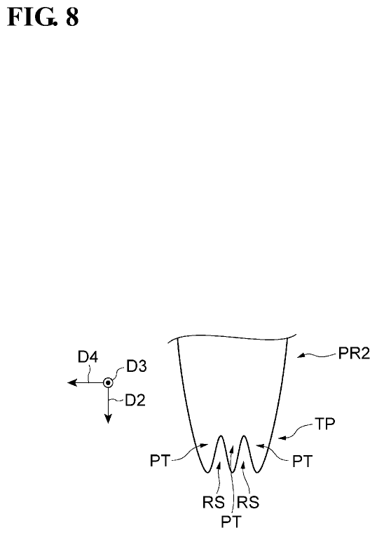

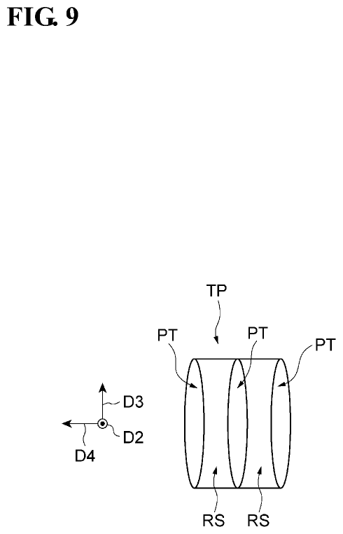

FIG. 8 is a side view of a part of a probe according to another embodiment. FIG. 9 is a plan view of an end portion of the probe in FIG. 8. A probe PR2 shown in FIGS. 8 and 9 has the same configuration as probe PR shown in FIGS. 2 to 4 except that the number of recessed portions RS is different. Probe PR2 includes a plurality of recessed portions RS. In fourth direction D4, recessed portions RS and protrusions PT are alternately arranged. According to probe PR2, the same effect as that of probe PR can be obtained. In fourth direction D4, since protrusions PT are evenly arranged, a force is uniformly applied to each of protrusions PT. Therefore, protrusions PT are less likely to be broken.

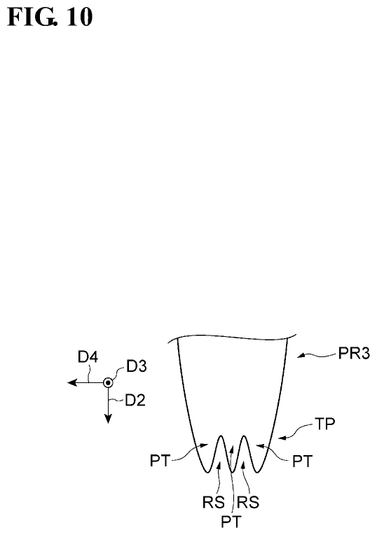

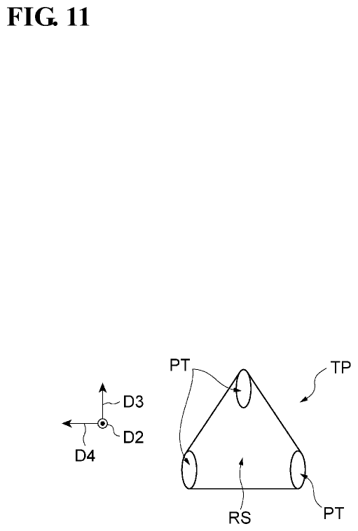

FIG. 10 is a side view of a part of a probe according to another embodiment. FIG. 11 is a plan view of an end portion of the probe in FIG. 10. A probe PR3 shown in FIGS. 10 and 11 has the same configuration as probe PR shown in FIGS. 2 to 4 except that the outer shape of end portion TP and the number and arrangement of protrusions PT are different. End portion TP of probe PR3 has a triangular shape in a plane orthogonal to second direction D2. Probe PR3 has, for example, three protrusions PT. Each of protrusions PT is located at each vertex of the triangular outline. According to probe PR3, the same effect as that of probe PR can be obtained. Since protrusions PT are evenly arranged in the plane orthogonal to second direction D2, a force is uniformly applied to each of protrusions PT. Therefore, protrusions PT are less likely to be broken.

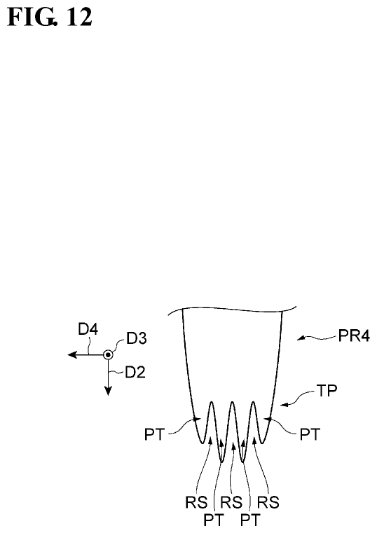

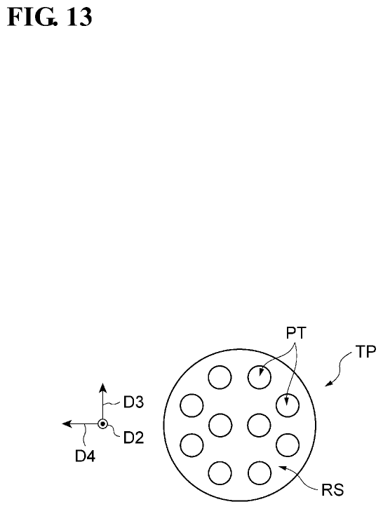

FIG. 12 is a side view of a part of a probe according to another embodiment. FIG. 13 is a plan view of an end portion of the probe in FIG. 12. A probe PR4 shown in FIGS. 12 and 13 has the same configuration as probe PR shown in FIGS. 2 to 4 except that the outer shape of end portion TP and the number and arrangement of protrusions PT are different. End portion TP of probe PR4 has a circular outer shape in a plane orthogonal to second direction D2. Probe PR4 has, for example, four or more protrusions PT. According to probe PR4, the same effect as that of probe PR can be obtained. Since protrusions PT are evenly arranged in the plane orthogonal to second direction D2, a force is evenly applied to each of protrusions PT. Therefore, protrusions PT are less likely to be broken.

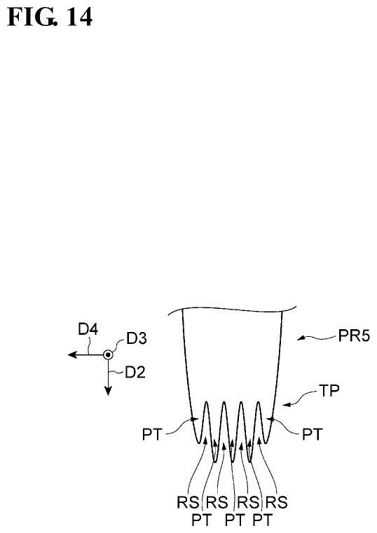

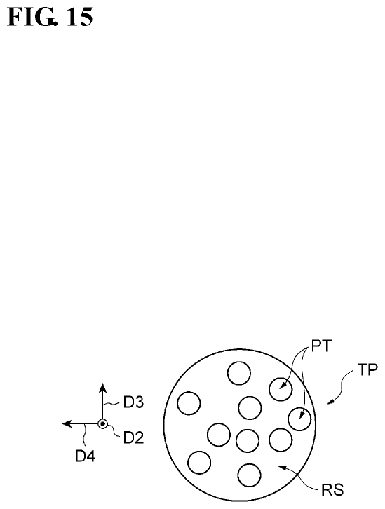

FIG. 14 is a side view of a part of a probe according to another embodiment. FIG. 15 is a plan view of an end portion of the probe in FIG. 14. A probe PR5 shown in FIGS. 14 and 15 has the same configuration as probe PR4 except for the arrangement of protrusions PT. Protrusions PT of probe PR5 are randomly arranged in a plane orthogonal to second direction D2. According to probe PR5, the same effect as that of probe PR4 can be obtained. Even when protrusions PT are randomly arranged in the plane orthogonal to second direction D2, if the number of protrusions PT is large, variation in a force applied to each of protrusions PT is small. Therefore, protrusions PT are less likely to be broken.

Although the preferred embodiments of the present disclosure have been described in detail above, the present disclosure is not limited to the above embodiments.

For example, probe PR may have only second portion P2. In this case, second direction D2 may coincide with a direction (Z-axis direction) orthogonal to surface 12a of electrode 12.

It should be understood that the embodiments disclosed herein are illustrative and non-restrictive in all aspects. The scope of the present invention is defined by the claims, not in the sense described above, and it is intended to embrace all modifications within the meaning and scope of equivalency of the claims.

What is claimed is:

1. A probe used in inspecting an electronic device, the probe comprising:
an end portion capable of contacting a surface of an electrode of the electronic device,
wherein the end portion has a recessed portion.

2. The probe according to claim 1, wherein the recessed portion is a groove extending so as to cross the end portion.

3. The probe according to claim 1, wherein a depth of the recessed portion is 100 μm or larger.

4. The probe according to claim 1, wherein a depth of the recessed portion is 1000 μm or smaller.

5. The probe according to claim 1, comprising:
a first portion and a second portion connecting to the first portion,
wherein the first portion extends in a first direction,
wherein the second portion extends in a second direction intersecting the first direction, and
wherein the second portion includes the end portion.

6. A probe device comprising:
a plurality of probes; and
a probe card to which the plurality of probes are to be attached,
wherein the plurality of probes are each the probe according to claim 1.

7. An electronic device inspection method comprising:
contacting the end portion of the probe according to claim 1 with the surface of the electrode; and
inspecting an electrical characteristic of the electronic device with the end portion of the probe and the surface of the electrode in contact with each other.

8. The electronic device inspection method according to claim 7, wherein, in the contacting, the end portion is brought into contact with a plurality of first regions of the surface of the electrode,
wherein, in the inspecting, a first electrical characteristic of the electronic device is inspected with the end portion of the probe and the plurality of first regions of the surface of the electrode in contact with each other,
wherein the inspection method further comprises:
after inspecting the first electrical characteristic, contacting the end portion of the probe with a plurality of second regions of the surface of the electrode; and
inspecting a second electrical characteristic of the electronic device with the end portion of the probe and the plurality of second regions of the surface of the electrode in contact with each other, and
wherein the plurality of first regions and the plurality of second regions are alternately arranged so that one second region of the plurality of second regions is disposed between adjacent ones of the plurality of first regions.
